(19) United States
(12) Patent Application Publication
(10) Pub. No.: US 2022/0271719 A1
(43) Pub. Date: Aug. 25, 2022

(54) SEMICONDUCTOR DEVICE

(71) Applicant: SUMITOMO ELECTRIC INDUSTRIES, LTD., Osaka (JP)

(72) Inventor: Takeshi KAWASAKI, Osaka (JP)

(21) Appl. No.: 17/557,594

(22) Filed: Dec. 21, 2021

(30) Foreign Application Priority Data
Feb. 22, 2021 (JP) 2021-026134

(51) Int. Cl. H03F 1/32; H03F 3/19

(52) U.S. Cl. CPC H03F 1/3241; H03F 3/19

(57) ABSTRACT

A semiconductor device includes an input terminal, an output terminal, an amplifier with an input, and a predistorter with an input electrically coupled to the input terminal and with an output electrically coupled to the input of the amplifier. The predistorter includes a first transistor.

### CROSS-REFERENCE TO RELATED APPLICATION

This application claims priority under 35 U.S.C. § 119 to Japanese Patent Application No. 2021-026134, filed Feb.22, 2021, the contents of which are incorporated herein by reference in their entirety.

### BACKGROUND

### 1. Field of the Invention

The present invention relates to a semiconductor device.

### 2. Description of the Related Art

Semiconductor devices are used as including an amplifier for amplifying a high-radio frequency signal and a distortion-correcting circuit for correcting non-linear distortion in the amplifier. As distortion-correcting circuits, analog predistorters (hereinafter, simply referred to as “predistorters”) that utilize the non-linearity of an analog element are often used in a relatively high-frequency domain such as a microwave band or a millimeter wave band.

Each of Patent Documents 1 and 2 discloses a predistorter for adjusting gain expansion, a transmission phase characteristic, and the like. In the predistorter, a capacitor is provided with respect to each of an input and output of a diode, and the diode is connected to a power circuit via resistance and an inductor element. The power circuit is different from an amplifier of a subsequent stage.

Patent Document 3 discloses a predistorter that enables gain expansion through a transistor of a previous stage. In this case, a diode is connected to an output side of the transistor, and operates to cancel phase distortion in an amplifier connected to a subsequent stage.

### CITATION LIST

### Patent Document

[Patent Document 1] Japanese Unexamined Patent Application Publication No. H11-355055

[Patent Document 2] Japanese Unexamined Patent Application Publication No. H9-232901

[Patent Document 3] Japanese Unexamined Patent Application Publication No. H4-252506

### SUMMARY

A semiconductor device of the present disclosure includes an input terminal, an output terminal, an amplifier with an input, and a predistorter with an input electrically coupled to the input terminal and with an output electrically coupled to the input of the amplifier, the predistorter including a first transistor.

### BRIEF DESCRIPTION OF THE DRAWINGS

FIG. 1 is a diagram illustrating an example of the configuration of a semiconductor device according to one embodiment;

FIG. 2 is a diagram for describing the outline of an example of a predistorter;

FIG. 3 is a diagram for describing an example of a through-type predistorter;

FIG. 4 is a diagram for describing an example of a shunt-type predistorter;

FIG. 5 is a circuit diagram of an example of the predistorter using a diode;

FIG. 6 is a diagram illustrating an equivalent circuit of the predistorter using the diode;

FIG. 7 is a graph illustrating an example of a voltage-current characteristic of the diode;

FIG. 8 is a graph illustrating an example of a reverse voltage-capacitance characteristic of the diode;

FIG. 9 is a diagram for describing a transmission characteristic of the predistorter using the diode;

FIG. 10 is a diagram illustrating an example of a line pattern of the diode;

FIG. 11 is a circuit diagram illustrating an example of the predistorter according to a first embodiment;

FIG. 12 is a diagram illustrating an example of an equivalent circuit of the predistorter according to the first embodiment;

FIG. 13 is a diagram illustrating an example of a drain voltage-drain current characteristic of an FET according to the first embodiment;

FIG. 14 is a diagram illustrating an example of a line pattern of the FET according to the first embodiment;

FIG. 15 is a circuit diagram illustrating an example of the predistorter according to a second embodiment;

FIG. 16 is a diagram illustrating an example of an equivalent circuit of the predistorter according to the second embodiment;

FIG. 17 is a circuit diagram illustrating an example of the semiconductor device according to the second embodiment;

FIG. 18 is a diagram illustrating an example of a line pattern of the semiconductor device according to the second embodiment;

FIG. 19 is a diagram illustrating an example of changes in characteristics of the predistorter in accordance with each voltage of a control terminal for gain expansion according to the second embodiment; and

FIG. 20 is a diagram illustrating an example of an improved output characteristic of the predistorter according to one or more embodiments.

### DESCRIPTION OF EMBODIMENTS

Related art information relevant to the present disclosure recognized by the inventor of this application will be provided below. In a predistorter using a diode, as an operating frequency increases, the size of the diode required to enable appropriate gain expansion is reduced. In contrast, when the size of the diode is reduced, the value of internal resistance of the diode increases. For this reason, conventional predistorters that use diodes are influenced by the internal resistance described above and consequently there may be cases where the gain expansion is reduced as the operating frequency increases.

in view of such issues of the related art, an object of the present disclosure is to provide a semiconductor device that enables greater gain expansion at higher operating frequencies.

The outline of one or more embodiments will be hereinafter described.

### Description of Embodiments of the Present Disclosure

In a first aspect of an embodiment of the present disclosure, a semiconductor device includes an input terminal, an output terminal, and an amplifier with an input. The semiconductor device includes a predistorter with an input electrically coupled to the input terminal and with an output electrically coupled to the input of the amplifier, the predistorter including a first transistor.

With a predistorter using a first transistor, by using a switching characteristic of the first transistor, increased power of an input signal can be obtained, while enabling gain expansion. For a predistorter that includes a diode, the size of the diode tends to be reduced as the operating frequency increases. In comparison to such a predistorter including the diode, in the predistorter using the first transistor described, reductions in the gain expansion can be mitigated, because internal resistance of the first transistor is less than that of the diode.

In a second aspect of the embodiment of the present disclosure, the predistorter according to the first aspect may further include an inductor element including a first end and a second end. The first end of the inductor element is electrically coupled to a source of the first transistor, and the second end of the inductor element is electrically coupled to a drain of the first transistor. With this arrangement, a predistorter can cancel internal capacitance, which may result in reductions in gain expansion, between a source and a drain of a first transistor, by using an inductor element. Therefore, greater gain expansion is enabled.

In a third aspect of the embodiment of the present disclosure, a predistorter according to the second aspect may further include a capacitive element including (i) a first end and a second end and (ii) a control terminal for gain expansion electrically coupled to a gate of a first transistor. The first end of the capacitive element is electrically coupled to the gate of the first transistor, and the second end of the capacitive element is electrically coupled to a ground terminal. With a control terminal for gain expansion, a voltage applied to the control terminal for gain expansion is varied and thus effective internal capacitance between a source and a drain of a first transistor are adjusted. Therefore, a gain expansion characteristic of a predistorter can be changed.

In a fourth aspect of the embodiment of the present disclosure, a semiconductor device according to any one of the first to third aspects further includes a semiconductor substrate. An input terminal, a predistorter, an amplifier, and an output terminal may be disposed on the semiconductor substrate.

In a fifth aspect of the embodiment of the present disclosure, a semiconductor device according to the third aspect may further include a semiconductor substrate including a first substrate region and a second substrate region that are divided by a straight line that passes through an input and output of a predistorter. An inductor element is disposed within the first substrate region, and a capacitive element and a control terminal for gain expansion are disposed within the second substrate region.

In a sixth aspect of the embodiment of the present disclosure, an amplifier according to any one of the first to fifth aspects may further include a second transisitor with a gate electrically coupled to an output of a predistorter and a drain electrically coupled to an output terminal.

In the fourth to sixth aspects of the embodiment of the present disclosure, in a semiconductor device that includes a predistorter and an amplifier, each component is effectively disposed, thereby obtaining great high-radio frequency characteristics, while reducing a mounting area of the semiconductor device.

### Details of Embodiments of the Present Disclosure

A semiconductor device according to embodiments of the present disclosure will be described with reference to the drawings. In the following description, the same or corresponding components are denoted by the same numerals, and description thereof may be omitted.

### Configuration of Semiconductor Device

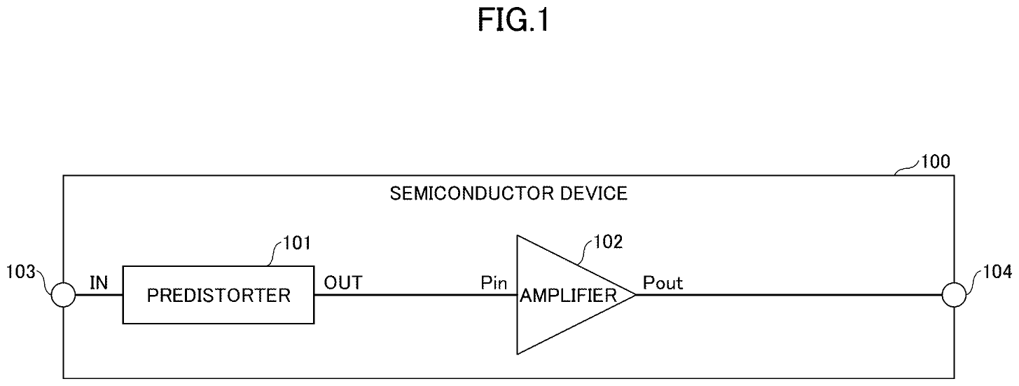

FIG. 1 is a diagram illustrating an example of the configuration of a semiconductor device according to one embodiment. For example, a semiconductor device 100 includes a predistorter 101 for correcting distortion in an amplifier 102, and includes the amplifier 102 for amplifying a high-radio frequency signal that is set at a relatively high frequency in a microwave band, a millimeter wave band, or the like. The semiconductor device 100 also includes an input terminal 103, an output terminal 104, and the like. The input terminal 103, the predistorter 101, the amplifier 102, and the output terminal 104 may be formed on the same semiconductor substrate. In FIG. 1, although only the terminals for inputting and outputting signals are illustrated, the semiconductor device 100 may also include one or more power terminals, one or more ground terminals, one or more control terminals, and the like, for example.

### Predistorter

In wireless communications, when distortion in the amplifier 102 arises, output power of the amplifier 102 exhibits good linearity in a low-input power domain, then exhibits degraded linearity of the output power in a high-input power domain.

In order to address the issue described above, various distortion corrections are used. Distortion correction techniques can be broadly classified as feedback, feedforward, and predistortion. In the amplifier 102 that operates at relatively high frequencies in a wide frequency band, such as a microwave band or a millimeter wave band, an analog predistorter (hereinafter, simply referred to as a “predistorter”) that utilizes the nonlinearity of an analog element is used. When the predistorter corrects distortion, a corrected amount of distortion is not large, because the distortion generated in the amplifier 102 is not used, in contrast to a feedback system or a feed forward system. However, unlike a feedback circuit that supports closed-loop control, the predistorter is better than other systems in terms of reductions in the circuit size and power consumption, because the predistorter can ensure stability and broadband characteristics.

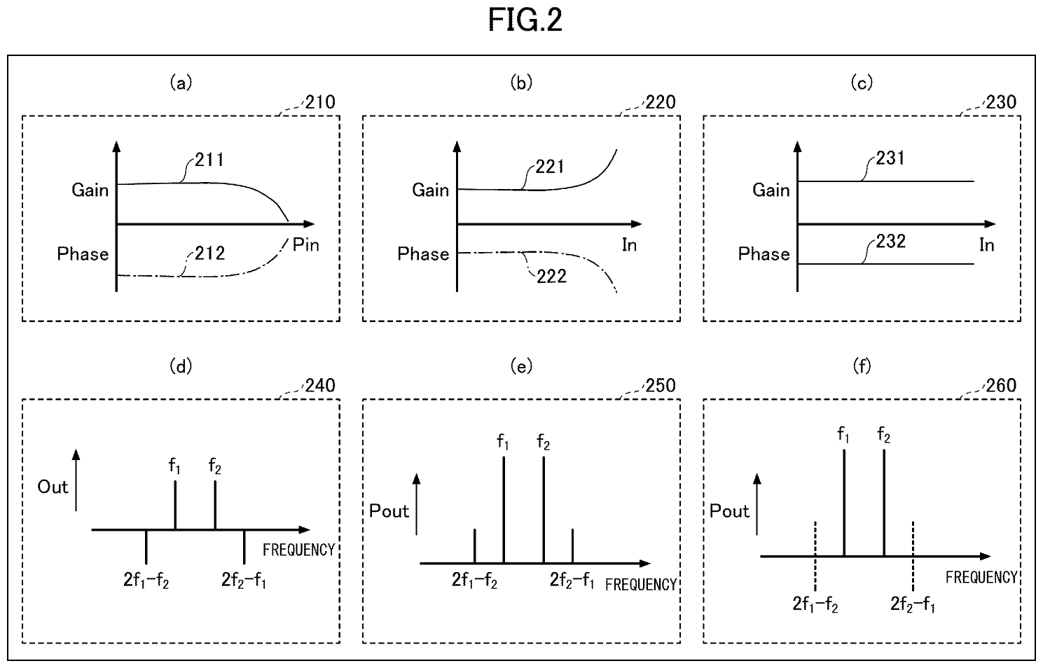

FIG. 2 is a diagram for describing the outline of the predistorter. In (a) of FIG. 2, the graph 210 illustrates an example of the characteristic of the amplifier 102 alone relating to the gain 211 and phase 212 with respect to the input power Pin. As illustrated in the graph 210, when the input power Pin of the amplifier 102 increases, output power becomes saturated and thus the gain 211 decreases while changing the phase 212. Thus, as illustrated in the graph 250 in (e) of FIG. 2, when two input signals at respective frequencies f₁ and f₂ are input to the amplifier 102 in a saturated domain, third-order intermodulation distortion at each of a frequency of 2f₁-f₂ and a frequency of 2f₂-f₁ arises in the amplifier 102.

The graph 220 in (b) of FIG. 2 illustrates an example of the characteristic of the predistorter 101 alone relating to the gain 221 and phase 222 with respect to the input power In. The predistorter 101 adjusts a bias condition or the like, by using the nonlinearity of an analog element such as a diode or a transistor. With this arrangement, a gain characteristic of the predistorter 101 that is the inverse of the gain characteristic of the amplifier 102, as well as a changed phase in the predistorter 101 that is the inverse of a changed phase in the amplifier 102, are obtained. For example, in the predistorter 101, as illustrated in the graph 220 in (b) of FIG. 2, as the input power increases, the gain 231 increases, while the phase 222 changes so as to be the inverse of the phase characteristic of the amplifier 102. With this arrangement, the predistorter 101 has the characteristic that cancels the intermodulation distortion in the amplifier 102, as illustrated in the graph 240 in (d) of FIG. 2, for example.

With this arrangement, good characteristics as a whole of the semiconductor device 100, from the input terminal 103 to the output terminal 104, are obtained as illustrated in the graph 230 in (c) of FIG. 2. In other words, even when the input power In input to the input terminal 103 increases, each of the gain 231 and phase 232 is not attenuated, because the output power Pout at the output terminal 104 is compensated. Additionally, the intermodulation distortion described above is eliminated or reduced, as illustrated in the graph 260 in (f) of FIG. 2.

### Configuration of Predistorter

The predistorter 101 may be one of two types, i.e., a through-type predistorter or a shunt-type predistorter.

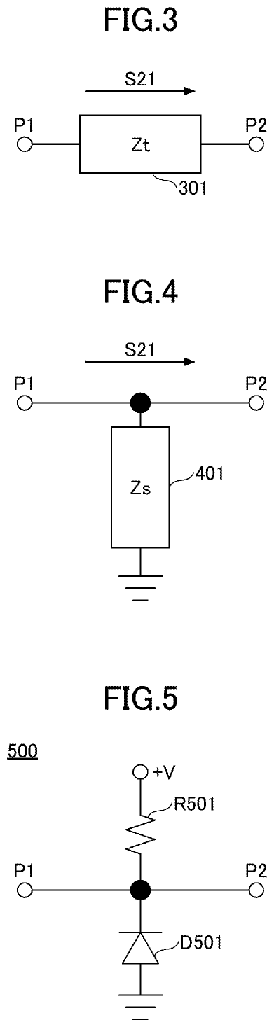

FIG. 3 is a diagram for describing the through-type predistorter. As illustrated in FIG. 3, a through-type predistorter 301 is coupled between an input port (input) P1 and an output port (output) P2. For example, an impedance of the through-type predistorter 301 is expressed by Zt, and a transmission characteristic of a signal from the input port P1 to the output port P2 is expressed by S21. In this case, Zt is set such that the loss defined based on S21 is close to zero in a situation of relatively high input power In, whereas the loss defined based on S21 is a predetermined loss (e.g., about 2 dB to about 6 dB) in a situation of relatively low input power In. With this arrangement, the through-type predistorter 301 has a characteristic that increases the gain 221 as the input power in increases, as illustrated in an example of the graph 220 of (b) of FIG. 2.

FIG. 4 is a diagram for describing the shunt-type predistorter. A shunt-type predistorter 401 is coupled in a signal line between a ground (ground of a circuit) and a node that is between the input port P1 and the output port P2, as illustrated in FIG. 4. An impedance of the shunt-type predistorter 401 is expressed by Zs, and a transmission characteristic of a signal from the input port P1 to the output port P2 is expressed by S21. In this case, when the input power In is relatively high, Zs is set to a sufficiently high impedance with respect to a characteristic impedance Z0 of the circuit, such that the loss defined based on S21 is minimized. When the input power In is relatively low, Zs is set to a reduced impedance such that the loss determined based on S21 is a predetermined loss (e.g., about 2 dB to 6 dB). With this arrangement, the shunt-type predistorter 401 has a characteristic that increases the gain 221 as the input power In increases, as illustrated in an example of the graph 220 of (b) of FIG. 2.

(Overview of predistorter using diode) Hereafter, the overview of predistorter using the diode will be described, as in the predistorters described in Patent Documents 1 to 3.

FIG. 5 is a circuit diagram illustrating a conventional predistorter that uses a diode. In FIG. 5, in a predistorter 500 using the diode, a cathode of a diode D501 is coupled to a signal line at a node between the input port P1 and the output port P2. An anode of the diode D501 is coupled to a ground. A power source +V is coupled to the cathode of the diode D501 via bias resistance R501. The predistorter 500 using the diode D501 is an example of the shunt-type predistorter 401.

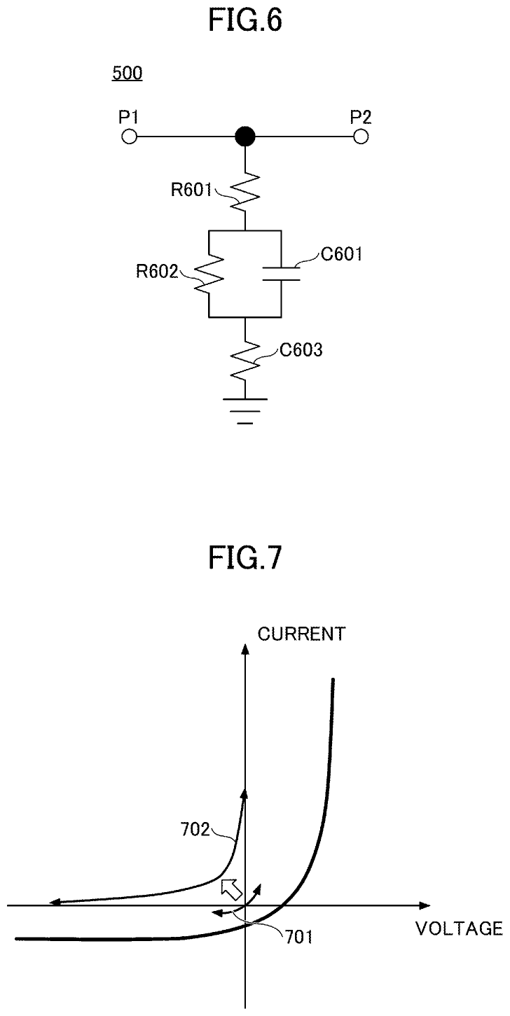

FIG. 6 is a diagram illustrating an equivalent circuit of the predistorter using the diode. The bias resistance R501, illustrated in FIG. 5, can be negligible in a high frequency domain, and thus is not illustrated in the equivalent circuit illustrated in FIG. 6. As illustrated in FIG. 6, the equivalent circuit of the predistorter 500 using the diode can be constructed by: a capacitor (capacitive element) C601, resistance R602 coupled in parallel with the capacitor C601, series resistance of 8601 and R603, and the like.

FIG. 7 is a graph illustrating an example of a voltage-current characteristic of the diode. In FIG. 7, when an input signal applied to the input port P1 increases, an average voltage 701 across the diode D501 decreases. For example, the average voltage 701 is changed to an average voltage 702.

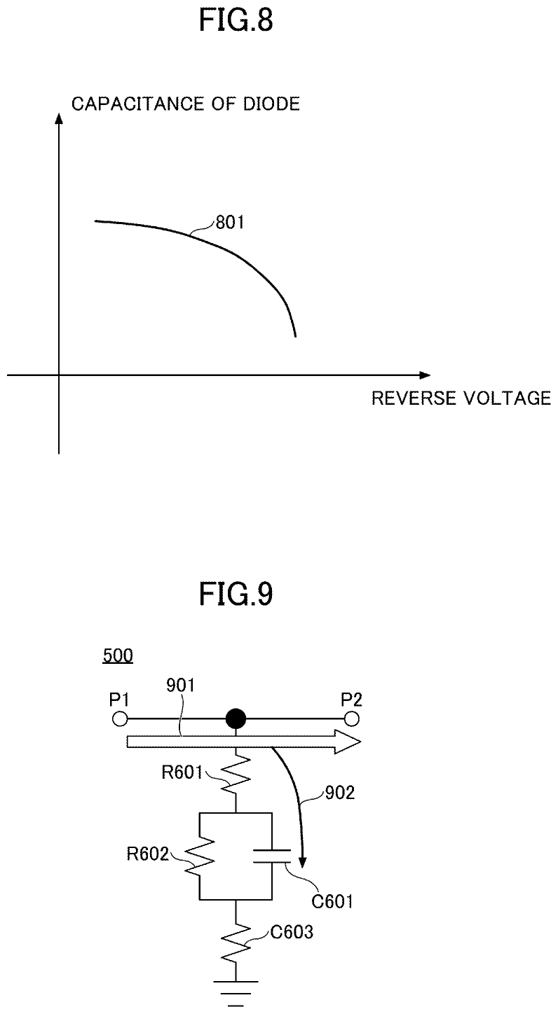

FIG. 8 is a graph illustrating an example of a reverse voltage-capacitance characteristic of the diode. As illustrated in the curve 801 in FIG. 8, the capacitance of the capacitor C601 is reduced when the reverse voltage of the diode D501 increases. With this arrangement, when the input signal applied to the input port P1 increases, the capacitance of the capacitor C601 derived from the diode D501 is reduced.

FIG. 9 is a diagram for describing the transmission characteristic of the predistorter using the diode. As illustrated in FIG. 9, power 902, which is a portion of power 901 transmitted from the input port P1 to the output port P2, is transmitted to a ground via resistance R601, the capacitor C601, and the resistance R603. As input power input to the input port P1 increases, the capacitance C601 of the diode D501 is reduced, and thus the power 902 is reduced. Therefore, the transmission characteristic is improved (losses are reduced). In general, an impedance Z of capacitance C, which depends upon a frequency f, is expressed as Z=1/(j2πfC). In this case, the capacitor C601 greatly influences the impedance Z as the frequency f increases. Accordingly, even at high radio frequencies, the size of the diode D501 needs to be smaller in order to obtain any desired improvements to transmission characteristic and gain expansion.

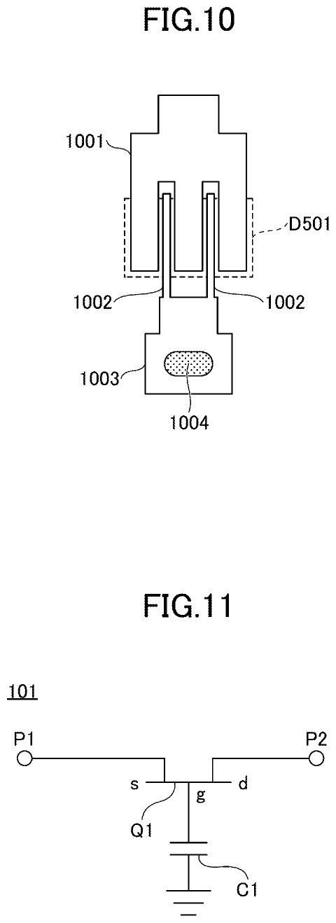

FIG. 10 is a diagram illustrating an example of line patterns of the diode. For example, the diode D501 is formed on a semiconductor substrate and is implemented with a line pattern 1001, a line pattern 1002, and the like. In the example in FIG. 10, the line pattern 1002 corresponds to an anode line and is coupled to a ground through a line pattern 1003 and a back-side via 1004. With this arrangement, if the size of the diode D501 is reduced, a greater value of the series resistance

R603 illustrated in FIG. 9 is obtained, because the pattern of each line pattern 1002 becomes narrower.

In such a manner, in the predistorter 500 using the diode D501, the size of the diode D501 required to enable appropriate gain expansion is reduced as the operating frequency of the predistorter increases. However, in the predistorter 500, when the size of the diode D501 is reduced, the value of the internal resistance R603 is increased. Thus, when the operating frequency is increased, the gain expansion may be reduced due to the increased internal resistance R603.

In light of the issue described above, in the semiconductor device 100 that includes an amplifier 102 and a predistorter 101, the predistorter 101 of the present disclosure that enables great gain expansion at an increased operating frequency is provided.

### First Embodiment

Hereafter, the predistorter according to a first embodiment of the present disclosure will be described.

### Configuration of Predistorter

FIG. 11 is a circuit diagram illustrating an example of the predistorter according to the first embodiment. As illustrated in FIG. 11, the predistorter 101 according to the first embodiment includes a first transistor Q1. The through-type predistorter 301 as illustrated in FIG. 3 is implemented using the first transistor Q1. The first transistor Q1 is implemented by, for example, a field effect transistor (FET) that is formed on the semiconductor substrate. A source of the first transistor Q1 is coupled to the input port P1, and a drain is coupled to the output port P2. A gate of the first transistor Q1 is coupled to a ground via, for example, a capacitor C1, in terms of high radio frequencies. In the present disclosure, the term “coupled” means not only a state of being physically connected, but also a state of being electrically connected (or coupled) via another element, circuit, or the like.

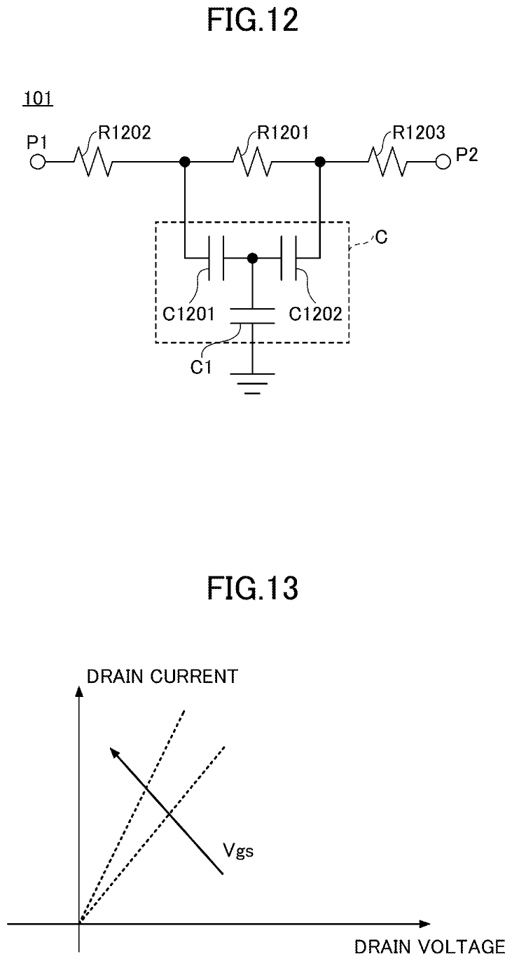

FIG. 12 is a diagram illustrating an equivalent circuit of the predistorter according to the first embodiment. As illustrated in FIG. 12, the equivalent circuit of the predistorter 101 according to the first embodiment can be configured by: resistance R1201, a capacitor C coupled in parallel with the resistance R1201, and series resistance of R1202 and R1203. The capacitor C is configured by internal capacitance C1201 and internal capacitance C1202 of the first transistor Q1, the capacitor C1 illustrated in FIG. 11, and the like.

### Operation and Effect of Predistorter

In the predistorter 101 illustrated in FIGS. 11 and 12, the through-type predistorter is implemented by using the switching characteristics of the first transistor (FET) Q1. For example, when the consideration for the above-described diode D501 is likewise applied to the source and gate of the first transistor Q1, a reverse voltage (=Vgs) of the source is assumed to increase as input power input to the input port P1 increases.

FIG. 13 is a diagram illustrating an example of a drain voltage-current characteristic of the FET according to the first embodiment. As illustrated in

FIG. 13, resistance (=drain voltage/drain current) between the source and the drain of the first transistor (FET) Q1 is reduced as Vgs increases. With this arrangement, as the input power input to the input port P1 increases, a resistance value of resistance R1201 between the source and drain is reduced. In this case, as illustrated in the graph 220 in (b) of FIG. 2, the predistorter 101 has a characteristic that increases the gain 221 as the input power in increases.

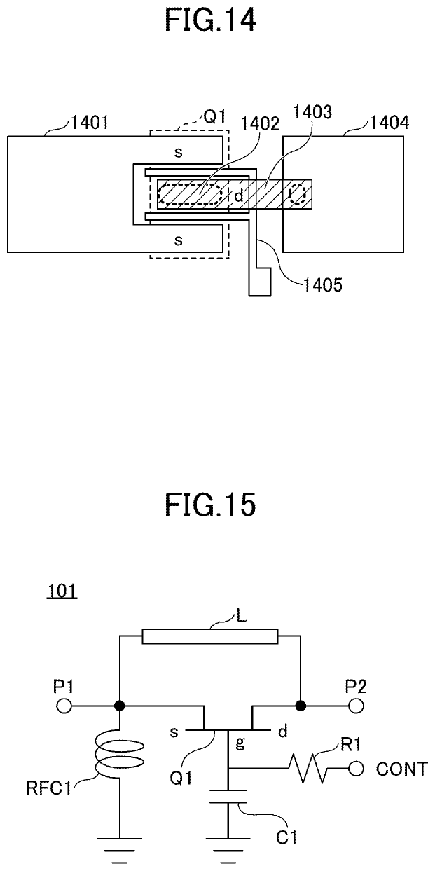

FIG. 14 is a diagram illustrating an example of a line pattern of the FET according to the first embodiment. The first transistor (FET) Q1 is formed on the semiconductor substrate. In the example in FIG. 14, the source of the first transistor Q1 is formed using a line pattern 1401, whereas the drain is implemented by using a line pattern 1402 and a line pattern 1403 or the like that couples the line pattern 1402 and a line pattern 1404, the line pattern 1403 being at a layer different from that of the line pattern 1402. In FIG. 14, each portion expressed by a dotted line indicates a via that electrically couples the line pattern 1403 and a given line pattern among the line pattern 1402 and the line pattern 1403.

As in the predistorter 500 using the diode D501, the size of the first transistor Q1 required to enable any appropriate gain expansion is reduced as the operating frequency increases. In this case, in the predistorter 101 using the first transistor Q1, the series resistance R1202 illustrated in FIG. 12 corresponds to the line pattern 1401 illustrated in FIG. 14, and the series resistance R1203 illustrated in FIG. 12 corresponds to the line pattern 1402 or the line pattern 1404 illustrated in FIG. 14. As illustrated in FIG. 14, because each of the line patterns 1401 to 1404 is not narrower than the anode line (line pattern 1002) of the diode D501 illustrated in FIG. 10, series resistance is unlikely to influence gain expansion, in comparison to the diode D501. With this arrangement, in the predistorter 101 according to the first embodiment, in the semiconductor device 100 that includes the amplifier 102 and the predistorter 101, great gain extension is enabled at a high operating frequency, in comparison to the predistorter 500 using the diode D501.

### Second Embodiment

Hereafter, the predistorter according to a second embodiment of the present disclosure will be described.

### Configuration of Predistorter

FIG. 15 is a circuit diagram illustrating an example of the predistorter according to a second embodiment. In addition to including the first transistor Q1 and the capacitor C1 of the predistorter 101 according to the first embodiment described in FIG. 11, the predistorter 101 according to the second embodiment includes an inductor element L, a choke coil RFC 1 for high radio frequencies, a resistive element R1, and a control terminal CONT for gain expansion, and the like. As illustrated in FIG. 15, one end of the inductor element L is coupled to the source of the first transistor Q1, and the other end of the inductor element L is coupled to the drain of the first transistor Q1. In this example, the inductor element L is formed by a microstrip line on a semiconductor substrate.

One terminal of the choke coil RFC1 is coupled to the source of the first transistor Q1, and the other terminal is coupled to a ground. In terms of direct current, the choke coil RFC1 is responsible for grounding the source and drain of the first transistor Q1 to be at a ground potential. It is desirable for the choke coil RFC1 to have a high impedance in terms of high radio frequencies and to have little (or negligible) effect on the transmission characteristic and matching characteristic of the predistorter 101. The control terminal CONT for gain expansion is coupled to the gate of the first transistor Q1 via resistance (resistive element) R1 and is used to apply a predetermined voltage to the gate of the first transistor Q1. As described above, in the present disclosure, the term “coupled” means not only a state of being physically connected, but also a state of being electrically connected (or coupled) via another element, circuit, or the like.

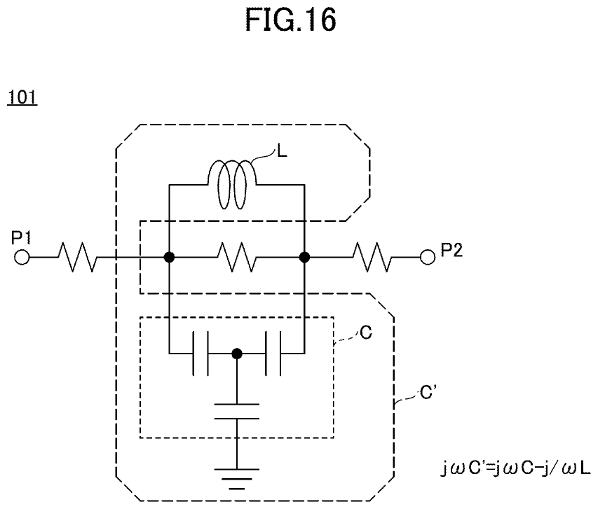

FIG. 16 is a diagram illustrating an equivalent circuit of the predistorter according to the second embodiment. As illustrated in FIG. 16, the equivalent circuit of the predistorter 101 according to the second embodiment includes an inductor element L, as well as including the equivalent circuit of the predistorter 101 according to the first embodiment described in FIG. 12. The inductor element L is coupled in parallel with the capacitor C that is configured by the internal capacitance C1201, the internal capacitance C1202, and the capacitor C1 of the first transistor Q1. The inductor element L has the effect of canceling capacitance of the capacitor C.

For example, as illustrated in FIG. 16, when a capacitive component determined based on a combination of the inductor element L and the capacitor C is given by C′, C′ is expressed by the condition of jωC′=jωC−j/ωL. With this arrangement, in the predistorter 101 according to the second embodiment, when a high operating frequency is set, the internal capacitance of the first transistor Q1 can be adjusted by using the inductor element L, without the need to reduce the size of the first transistor Q1.

As described above, according to the predistorter 101 according to the second embodiment, in the semiconductor device 100 that includes the amplifier 102 and the predistorter 101, great gain expansion is enabled at a higher operating frequency, without depending on the size of the first transistor Q1.

### Circuit Configuration of Semiconductor Service

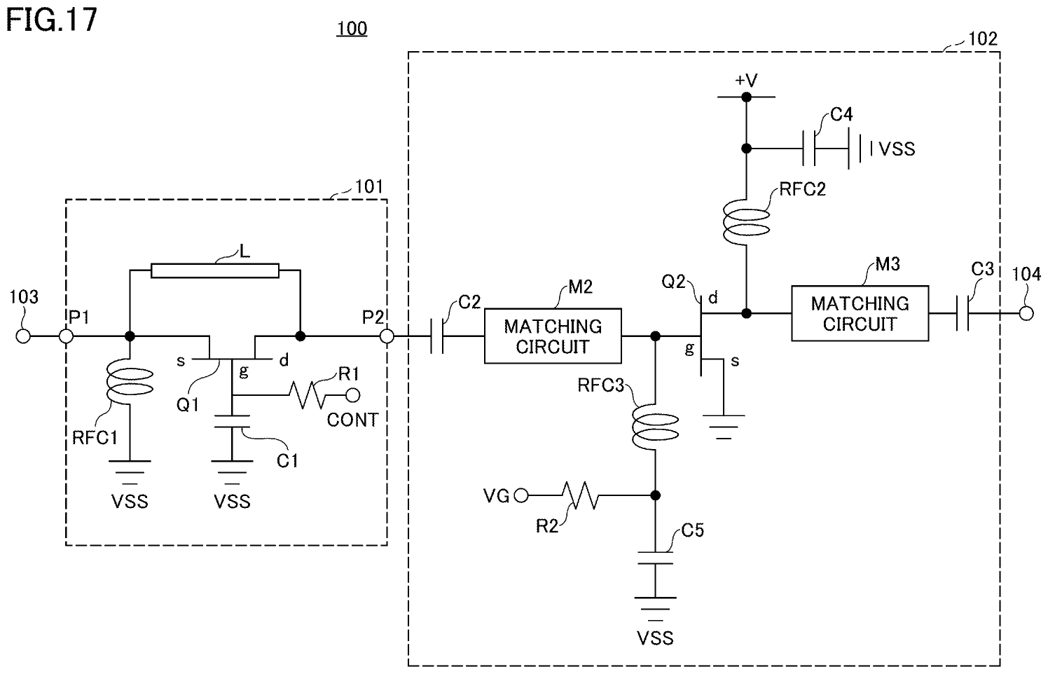

FIG. 17 is a circuit diagram illustrating an example of the semiconductor device according to the second embodiment. As illustrated in FIG. 17, the input port (input) P1 of the predistorter 101 is coupled to the input terminal 103 of the semiconductor device 100, and the output port (output) P2 of the predistorter 101 is coupled to the input of the amplifier 102.

The predistorter 101 includes the first transistor (FET) Q1 and the inductor element L. One end of the inductor element L is coupled to the source of the first transistor Q1, and the other end of the inductor element L is coupled to the drain of the first transistor Q1. The predistorter 101 also includes the capacitor (capacitive element) C1 and the control terminal CONT for gain expansion. One terminal of the capacitor C1 is coupled to the gate of the first transistor Q1, and the other terminal of the capacitor C1 is coupled to a ground terminal VSS. The control terminal CONT for gain expansion is coupled to the gate of the first transistor Q1 via a resistive element R1.

The amplifier 102 includes the second transistor (FET) Q2. As an example, an amplifier circuit in which the source is grounded may be implemented by the amplifier 102. In the example of FIG. 17, the gate of the second transistor Q2 is coupled to the output port (output) P2 of the predistorter 101 via a matching circuit M2 for impedance matching and a capacitor C2. The gate of the second transistor Q2 is coupled to one terminal of a choke coil RFC3 for high radio frequencies. The other terminal of the choke coil RFC3 is coupled to a around via a capacitor C5, in terms of high radio frequencies. The other terminal of the choke coil RFC3 is coupled to a control terminal VG for supplying a gate voltage of the second transistor Q2, via a resistive element R2.

The drain of the second transistor Q2 is coupled to the output terminal 104 of the semiconductor device 100 via a matching circuit M3 for impedance matching and a capacitor C3. The drain of the second transistor Q2 is coupled to a power supply terminal +V via a choke coil RFC2 for high radio frequencies. A capacitor C4 is coupled between the ground terminal VSS and a terminal of the choke coil RFC2 toward the power supply terminal +V, and the terminal of the choke coil RFC2 toward the power supply terminal +V is coupled to a ground in terms of high radio frequencies.

The circuit configuration of the amplifier 102 illustrated in FIG. 17 is one example. The amplifier 102 may be, for example, a multistage amplifier circuit or the like including two or more transistors.

### Example of Line Patterns of Semiconductor Device

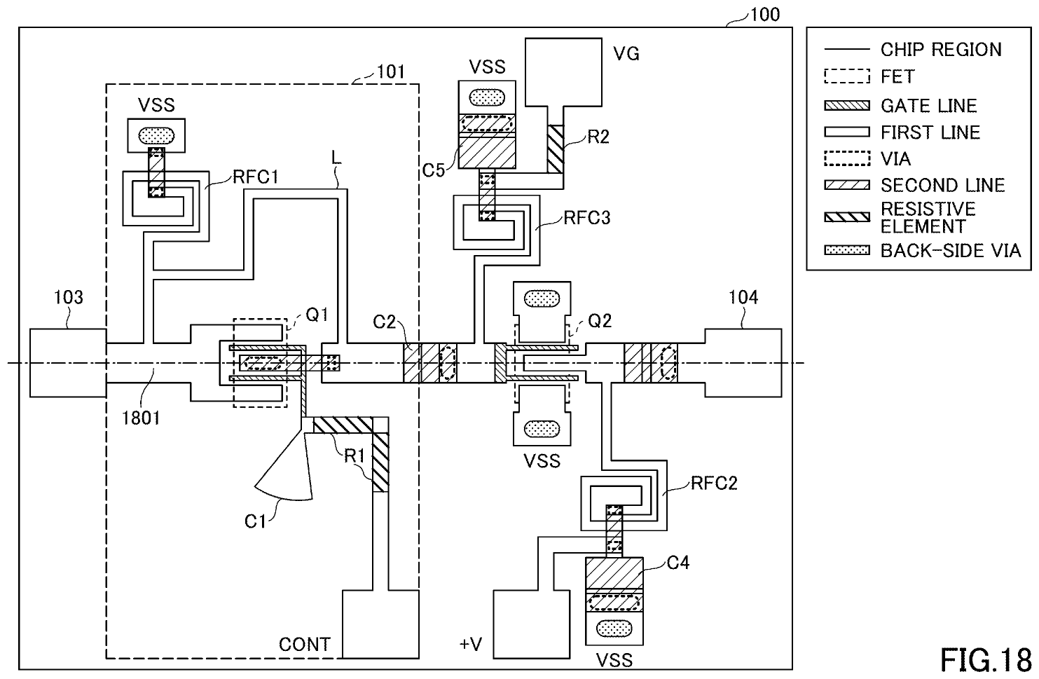

FIG. 18 is a diagram illustrating an example of the line patterns of the semiconductor device according to the second embodiment. The semiconductor device 100 is provided on the same semiconductor substrate that includes, for example, GaAs (gallium arsenide) or the like. In FIG. 18, a first line is formed of, a metal line on the semiconductor substrate (e.g., Au line), and a second line is formed of a metal line at a layer different from the first line on the semiconductor substrate, for example. In FIG. 18, the first line and the second line are coupled to each other by a plurality of vias. A portion of the first line at each back-side via is grounded via a given back-side via to be at a ground potential.

In the example of FIG. 18, as an example, the inductor element L is formed as a microstrip line, between the first line (metal, e.g., Au, line of which the thickness t is 2 μm) on the semiconductor substrate (GaAs substrate of which the thickness t is 50 μm) and a conductive metal layer provided on the back surface of the semiconductor substrate. The first line is formed such that the width W of the first line is 10 μm and the length L thereof is 280 μm, for example. A gate line of the first transistor Q1 is formed with the first line to have the gate length Lg of 0.1 μm and the gate width Wg of 20 μm×2, for example. Further, as an example, the capacitor C1 is formed with the first layer as an open stub having capacitance of 0.15 pF. For example, a resistance value of the resistive element R1 is 1 kΩ, and an inductance value of the choke coil RFC1 is 240 pH, for example.

When the semiconductor substrate is divided into two substrate regions that are divided by a straight line 1801 coupling the input and the output of the predistorter 101, the inductor element L is formed within one substrate region, and both the capacitor C and the control terminal CONT for gain expansion may be formed within another substrate region.

### Control Terminal for Gain Expansion

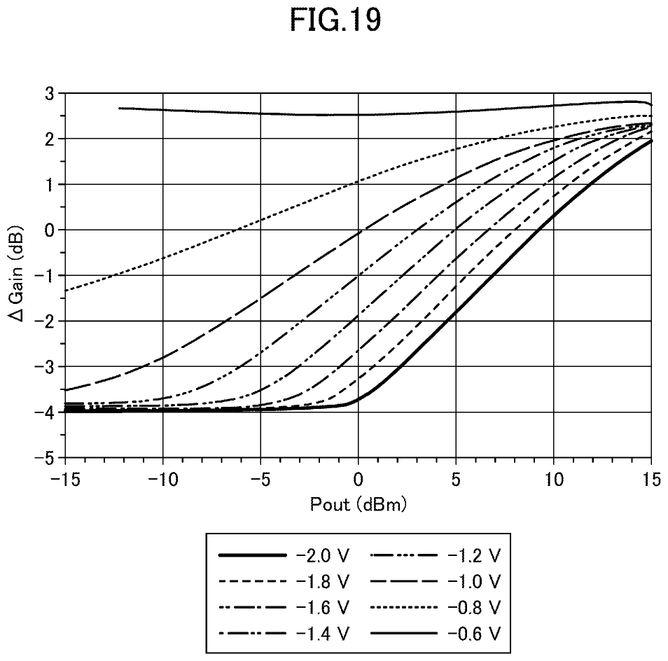

FIG. 19 is a diagram illustrating an example of changes in characteristics of the predistorter in accordance with each voltage of the control terminal for gain expansion according to the second embodiment. The choke coil RFC1 of the predistorter 101 illustrated in FIGS. 17 and 18 is responsible for grounding the source and drain of the first transistor Q1, in terms of direct current. With this arrangement, as illustrated in the example in FIG. 19, the predistorter 101 can adjust the gain expansion characteristic based on the bias voltage applied to the control terminal CONT for gain expansion.

In FIG. 19, the horizontal axis represents the output power of the predistorter 101, and the vertical axis represents a gain difference for the predistorter 101. As illustrated in FIG. 19, by setting a smaller magnitude of the bias voltage to be applied to the control terminal CONT for gain expansion, a greater slope for the gain expansion characteristic can be set.

### Effect of Predistorter

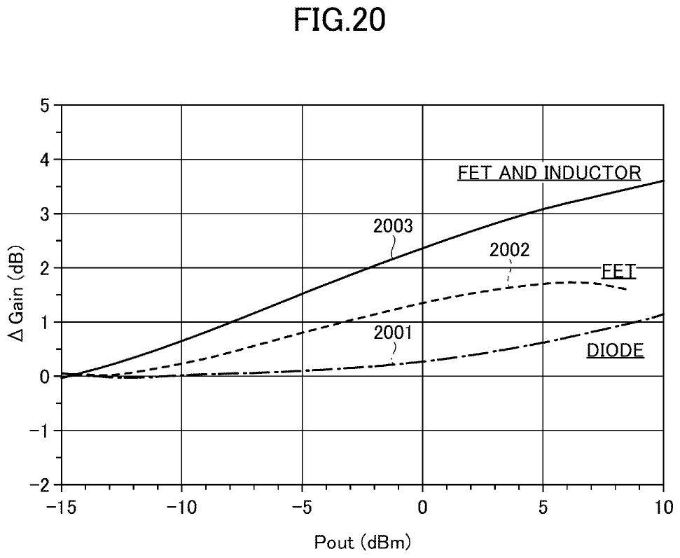

FIG. 20 is a diagram illustrating an example of an improved output characteristic of the predistorter according to one or more embodiments of the present disclosure. In FIG. 20, the horizontal axis expresses the output power of the predistorter, and the vertical axis expresses a gain difference for the predistorter. In FIG. 20, the curve 2001 indicates an example of the gain expansion characteristic of the predistorter 500 using the diode D501 illustrated in FIG. 5, as a comparative example.

The curve 2002 indicates an example of the gain expansion characteristic of the predistorter 101 using the first transistor (FET) Q1 according to the first embodiment, as illustrated in FIG. 11. As illustrated in the curve 2002 in FIG. 20, in the predistorter 101 according to the first embodiment, it can be seen that the gain expansion characteristic of the predistorter 101 is improved in a relatively high-frequency domain, such as a microwave band or a millimeter wave band.

The curve 2003 indicates an example of the gain expansion characteristic of the predistorter 101 using the first transistor (FET) Q1 and the inductor element L according to the second embodiment, as illustrated in the example in FIG. 15. As illustrated in the curve 2003 in FIG. 20, in the predistorter 101 according to the second embodiment, it can be seen that the gain expansion characteristic of the predistorter 101 is further improved in the relatively high-frequency domain, such as a microwave band or a millimeter wave band.

As described above, in the semiconductor device 100 that includes the amplifier 102 and the predistorter 101 according to one or more embodiments of the present disclosure, great gain expansion is enabled at higher operating frequencies.

One or more embodiments and the like of the present disclosure have been described above. However, the present disclosure is not limited to the embodiments. Various modifications, changes, substitutions, additions, deletion, or any combination of embodiments can be made within the scope set forth in the present disclosure.

What is claimed is:

1. A semiconductor device comprising:
an input terminal;
an output terminal;
an amplifier with an input; and
a predistorter with an input electrically coupled to the input terminal and with an output electrically coupled to the input of the amplifier, the predistorter including a first transistor.

2. The semiconductor device according to claim 1, wherein the predistorter further includes an inductor element including a first end and a second end,
wherein the first end of the inductor element is electrically coupled to a source of the first transistor, and the second end of the inductor element is electrically coupled to a drain of the first transistor.

3. The semiconductor device according to claim 2, wherein the predistorter further includes
a capacitive element including a first end and a second end, and
a control terminal for gain expansion, the control terminal being electrically coupled to a gate of the first transistor, and
wherein the first end of the capacitive element is electrically coupled to the gate of the first transistor, and the second end of the capacitive element is electrically coupled to a ground terminal.

4. The semiconductor device according to claim 1, further comprising a semiconductor substrate, wherein the input terminal, the predistorter, the amplifier, and the output terminal are disposed on the semiconductor substrate.

5. The semiconductor device according to claim 3, further comprising a semiconductor substrate including a first substrate region and a second substrate region that are divided by a straight line that passes through the input and output of the predistorter,
wherein the inductor element is disposed within the first substrate region, and the capacitive element and the control terminal for gain expansion are disposed within the second region.

6. The semiconductor device according to claim 1, wherein the amplifier further includes a second transisitor with a gate electrically coupled to the output of the predistorter and with a drain electrically coupled to the output terminal.
